(19) United States
(12) Patent Application Publication
(10) Pub. No.: US 2026/0304719 A1
(43) Pub. Date: Oct. 1, 2026

(54) FIELD CUSTOMIZABLE AIRFLOW SYSTEM FOR A COMMUNICATIONS BOX

(71) Applicant: Manufacturing Resources International, Inc., Alpharetta, GA (US)

(72) Inventor: Mike Brown, Cumming, GA (US)

(21) Appl. No.: 19/707,517

(22) Filed: Jun. 15, 2026

Related U.S. Application Data
(63) Continuation of application No. 17/896,142, filed on Aug. 26, 2022, now Pat. No. 12,684,747.
Application No. 17/896,142 is a division of application No. 17/061,903, filed on Oct. 2, 2020, now Pat. No. 11,477,923.

(51) Int. Cl. H05K 7/20; G02F 1/1333

(52) U.S. Cl. CPC H05K 7/20972; G02F 1/133385; H05K 7/20145

(57) ABSTRACT

A communications box for a display assembly providing directed airflow is disclosed. The communications box includes a partition with at least one aperture. The partition separates an interior of the communications box into an upper area and a lower area. The at least one aperture is positioned adjacent to a first electronic component of the communications box which requires active cooling. A solid surface of the partition is positioned adjacent to a second electronic component of the communications box which does not require active cooling.

### CROSS-REFERENCE TO RELATED APPLICATIONS

This application is a continuation of U.S. patent application Ser. No. 17/896,142 filed Aug. 26, 2022, which is a divisional of U.S. patent application Ser. No. 17/061,903 filed Oct. 2, 2020 (now U.S. Pat. No. 11,477,923), the disclosures of each of which are hereby incorporated by reference as if fully restated herein.

### TECHNICAL FIELD

Exemplary embodiments relate generally to a field customizable airflow system for a communications box and systems and methods related to the same.

### BACKGROUND AND SUMMARY OF THE INVENTION

It has become increasingly desirable to include certain electronic equipment with display assemblies featuring electronic displays. Such electronic equipment may include, for example, communications equipment, sensing equipment, combinations thereof, and the like. For example, advertising or announcements may be displayed at the electronic displays and internet connectivity may be facilitated by the electronic equipment. Such electronic displays and electronic equipment may be provided in ruggedized housings to protect the electronic displays and equipment from harsh environmental conditions. Sometimes, the electronic equipment is provided in a box above the electronic displays. The elevated position of the box may facilitate signal propagation and reception. Other times, the box is provided at other locations within the ruggedized housing, such as behind one or more of the electronic displays or below the electronic displays.

The electronic equipment may be placed in various locations within the box, and the various pieces of equipment may have different airflow needs. For example, some such equipment may require airflow for cooling and/or proper operation. Lack of adequate airflow may result in equipment failure, improper operation, or undesirable consequences. Other such equipment may not require cooling and/or may not be configured to handle moisture, debris, or other material that might be present in the airflow. Furthermore, it may be desirable to change the type, location, or the like of the electronic equipment in the box over time. For example, equipment may be upgraded, equipment may be removed, new equipment may be developed or desired, communications protocols may change (thus requiring new equipment), or the like. Therefore, what is needed is a field customizable airflow system for a communications box.

A field customizable airflow system for a communications box is provided. A display assembly may include one or more electronic display subassemblies and a communications box. The communications box may include one or more electronic components, at least some of which may have different airflow requirements. One or more convection aperture plates may be provided within the communications box. Each of the convection aperture plates may comprise one or more apertures. The apertures may be provided adjacent to planned or actual locations of at least certain ones of the electronic components to force air to pass by at least certain ones of the electronic components. In this way, areas of relatively high airflow and/or cooling and areas of relatively low airflow and/or cooling may be engineered within the communications box. For example, the convection aperture plates may be utilized to create a single airflow pathway, or multiple airflow pathways for air within the communications box as required by the various pieces of electronic equipment. The convection aperture plates may comprise any number, size, shape, location, or configuration of apertures to accommodate airflow needs of the new and/or updated electronic components.

Such convection aperture plates may be provided in new display assemblies, or retrofitted into existing display assemblies. In the event that certain electronic equipment is added, removed, or changed from the communications box, such as due to failure, the need or desire to upgrade, the need or desire to add new equipment, combinations thereof, or the like, the convection aperture plate(s) may be replaced, removed, or added as needed to provide appropriate airflow through the communications box to address the airflow needs of the electronic equipment.

Air in the communications box may comprise ingested ambient air. In exemplary embodiments, the air ingested into the communications box may comprise a portion of ambient air ingested into the display assembly at an intake, where a second portion of the ambient air ingested at the intake may travel into or along the electronic display subassemblies. In other exemplary embodiments, the air in the communications box may comprise circulating gas and thermal devices may be provided with the communications box to remove heat from the circulating gas.

Further features and advantages of the systems and methods disclosed herein, as well as the structure and operation of various aspects of the present disclosure, are described in detail below with reference to the accompanying figures.

### BRIEF DESCRIPTION OF THE DRAWINGS

In addition to the features mentioned above, other aspects of the present invention will be readily apparent from the following descriptions of the drawings and exemplary embodiments, wherein like reference numerals across the several views refer to identical or equivalent features, and wherein:

FIG. 1 is a front perspective view of an exemplary display assembly;

FIG. 2 is a side sectional view of the display assembly of FIG. 1 illustrating exemplary airflow;

FIG. 3 is a front perspective view of another exemplary display assembly;

FIG. 4 is a side sectional view of the display assembly of FIG. 3 illustrating exemplary airflow;

FIG. 5 is a side sectional view of the display assembly of FIG. 3 illustrating other exemplary airflow;

FIG. 6 is a detailed sectional view of an exemplary communications box with an exemplary convection aperture plate;

FIG. 7 is a detailed sectional view of the communications box of FIG. 6 with another exemplary convection aperture plate;

FIG. 8 is a detailed sectional view of another exemplary communications box with other exemplary airflow;

FIG. 9 is a top view of another exemplary convection aperture plate;

FIG. 10 is a top view of another exemplary convection aperture plate;

FIG. 11 is a flow chart with exemplary logic for installing the convection aperture plates;

FIG. 12 is a sectional perspective view of another exemplary communications box with another exemplary convection aperture plate for exemplary electronic components;

FIG. 13 is a sectional perspective view of another exemplary communications box with another exemplary convection aperture plate for other exemplary electronic components; and

FIG. 14 a sectional perspective view of another exemplary communications box with another exemplary convection aperture plate for other exemplary electronic components.

### DETAILED DESCRIPTION OF EXEMPLARY EMBODIMENT(S)

Various embodiments of the present invention will now be described in detail with reference to the accompanying drawings. In the following description, specific details such as detailed configuration and components are merely provided to assist the overall understanding of these embodiments of the present invention. Therefore, it should be apparent to those skilled in the art that various changes and modifications of the embodiments described herein can be made without departing from the scope and spirit of the present invention. In addition, descriptions of well-known functions and constructions are omitted for clarity and conciseness.

Embodiments of the invention are described herein with reference to illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

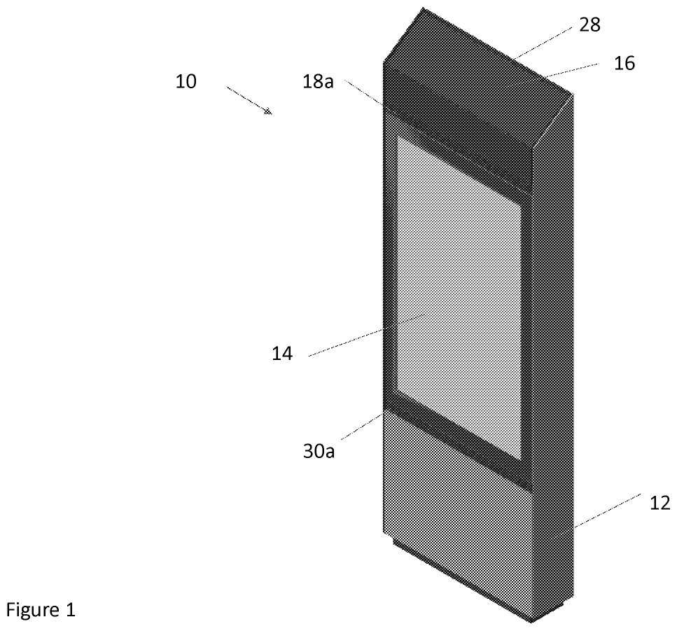

FIG. 1 illustrates an exemplary display assembly 10. The assembly 10 may comprise one or more housings 12. The assembly 10 may comprise one or more electronic display subassemblies 14. For example, without limitation, a first and second electronic display subassembly 14 may be positioned in a back-to-back arrangement within the housing 12, though any number and location of such electronic display subassemblies 14 may be utilized. The housing 12 may comprise a frame and/or a full or partial enclosure for each of the electronic display subassemblies 14. The electronic display subassemblies 14 may be moveably mounted to said housing 12.

Each electronic display subassemblies 14 may comprise an electronic display layer, a backlight, one or more airflow pathways, electronic components (e.g., processors, electronic storage devices, timing and control boards, video players, combinations thereof, or the like), one or more optical films, diffusion layers, fans, combinations thereof, or the like. The electronic display subassemblies 14 may comprise of any type of electronic display including, but not limited to, LCD displays, LED displays, plasma displays, OLED displays, or the like. Such electronic displays may be directly backlit, edge lit, combinations thereof, or the like.

A communications box 16 may be provided above the electronic display subassemblies 14, though other locations for the communications box 16 may be utilized. More than one communications box 16 may be utilized. For example, without limitation, the communications box 16 may alternatively or additionally be positioned behind or between one or more of the electronic display subassemblies 14, below the electronic display subassemblies 14, combinations thereof, or the like. In exemplary embodiments, the communications box 16 comprises materials configured to permit the transmission and/or receipt of electronic signals, such as, but not limited to, radio waves, Wi-Fi, near field communication, cellular networks signals, combinations thereof, and the like. At least a portion of the communications box 16 may be formed by the housing 12, though the communications box 16 may comprise a separate housing. The communications box 16 may be located immediately adjacent to the housing 12 or may be elevated above the housing 12, for example without limitation. The communications box 16 may define a cuboid shape, though any shape may be utilized.

One or more intakes 18 may be located at the housing 12. One or more exhausts 30 may be located at the housing 12. In exemplary embodiments, an intake 18 is located above each of the electronic display subassemblies 14 and an exhaust 30 is located below each of the electronic display subassemblies 14, though any location and number of the intakes 18 and exhausts 30 may be utilized. The intakes 18 may be configured to ingest ambient air while the exhausts 30 may be configured to exhaust ambient air. Airflow pathways may be provided within the housing 12 between the intakes 18 and the exhausts 30. Such airflow pathways may extend within, or along, the electronic display subassemblies 14.

The communications box 16 may comprise one or more vents 28 for exhausting ambient air. In exemplary embodiments, the vent 28 is located along an upper surface of the communications box 16, though any number and locations of vents 28 may be utilized. The vent 28 may be configured to exhaust at least a portion of the ambient air ingested at the intakes 18. Airflow pathways may extend from the intakes 18 to the vents 28.

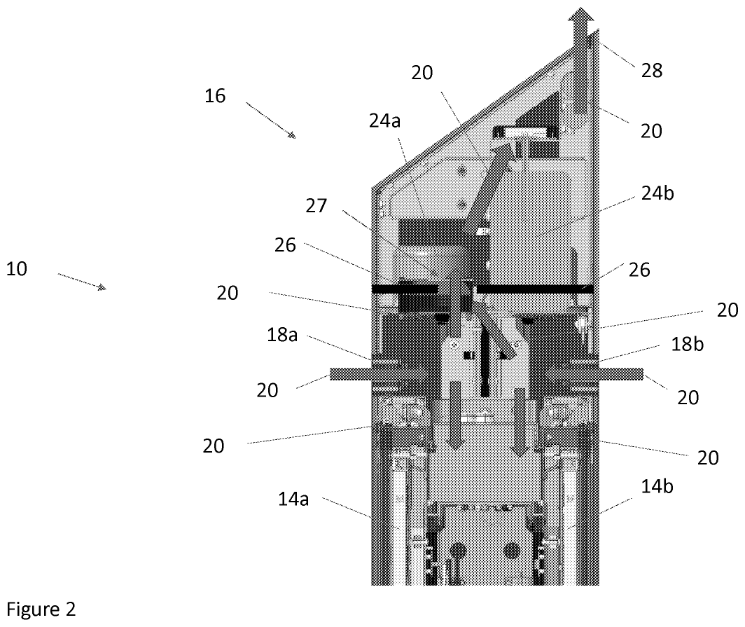

FIG. 2 illustrates a detailed sectional view of the communications box 16. One or more electronic components 24 may be located within the communications box 16. Such electronic components 24 may include, but are not limited to, Wi-Fi devices, network communication devices, internet modems, cellular network devices, near field communication devices, antenna, radio transmitters, radio receivers, satellite communications equipment, combinations thereof, or other communications equipment. Such electronic components 24 may alternatively or additionally include, but are not limited to, airflow velocity sensors, airflow rate sensors, moisture sensors, air quality or composition sensors (e.g., for detecting pollutants, toxins, certain chemicals or other substances, combinations thereof, or the like), temperature sensors, humidity sensors, pressure sensors, accelerometers, magnetometers, altimeters, incline sensors, microphones, ambient light sensors, cameras, combinations thereof, or other sensors. Such electronic components 24 may alternatively or additionally include, but are not limited to, computerized devices, electronic storage devices, processers, servers, video players, timing and control boards, speakers, amplifiers, cameras, microphones, location detection devices, GPS devices, air quality sensors, combinations thereof, or other equipment for operating the display assemblies 10 or gathering information. Any number, kind, or type of electronic components 24 may be utilized in any combination. The same or different electronic components 24 may be used across different display assemblies 10. Each of the electronic components 24 may have the same or different airflow needs for proper and/or optimal operation, such as, but not limited to, for detecting characteristics of ambient air, longevity, and/or cooling. For example, without limitation, certain sensors may require relatively low air velocity to properly function, while certain communication devices may require relatively high air velocity to adequately remove heat. As yet another example, certain electronic devices may not be configured to handle moisture, debris, pollutants, and/or temperatures of certain airflow, such as, but not limited to, ambient air, while other components may be so configured.

A convection aperture plate 26 may be provided within the communications box 16. The convection aperture plate 26 may comprise one or more apertures 27 positioned to direct airflow to all or some of the electronic components 24. The apertures 27 may be of the same, or varying size and shape and may be provided in any arrangement of configuration. Any number of apertures 27 may be provided in any size, shape, or the like.

Each of the electronic components 24 may have varying airflow needs. The convection aperture plate 26 may be designed with apertures 27 at select locations to accommodate such airflow needs. Furthermore, it may be desirable to change out various electronic components 24. For example, without limitation, different customers or users may desire different electronic components 24. As another example, without limitation, the electronic components 24 may be changed or upgraded over time to provide improved performance, integrate with other networks, operate under new protocols, or the like. The convection aperture plates 26 provided across various assemblies 10 may be of the same or different design to accommodate different types and/or arrangement of electronic equipment 24. Alternatively, or additionally, the convection aperture plate(s) 26 provided in a particular assembly 10 may be changed out or otherwise altered to reflect changing airflow requirements, such as when new equipment 24 is added, existing equipment 24 is removed, equipment 24 is rearranged, or equipment 24 is upgraded, any combination thereof, or the like.

The convection aperture plate 26 may be configured to have a footprint matching interior dimensions of the communications box 16. The convection aperture plate 26 may be substantially planar and create a barrier within the communications box 16 such that air must travel through the apertures 27 to be exhausted through the vent 28. The convection aperture plate 26 may define a footprint substantially matching a footprint of the communications box 16.

In exemplary embodiments, the convection aperture plate 26 may be configured to provide apertures 27 adjacent to the planned or actual location of certain electronic equipment 24 in the communications box 16, but not other such electronic equipment 24 in the communications box 16. The convection aperture plate 26 may form a barrier within the communications box 16 where said apertures 27 facilitate airflow to particular locations within the communications box 16 while preventing or impeding airflow to other locations within the communications box 16. For example, without limitation, apertures 27 of particular size or shape may be placed adjacent to the actual or planned location of certain ones of the electronic components 24 requiring airflow. The size, shape, and locations of the apertures 27 may be provided to facilitate airflow to the adjacent electronic components 24 to meet such airflow needs. Other electronic components 24 may not require airflow, and/or it may not operate optimally under forced airflow conditions. No such apertures 27 may be provided at the convection aperture plate 26 near actual or planned locations of electronic components 24 not requiring airflow and/or requiring other airflow conditions. For example, without limitation, the convection aperture plate 26 may comprise a solid material or otherwise be fluidly sealed at such locations to prevent or impede airflow to such equipment 24.

Ambient air 20 may be ingested into the assembly 10. In exemplary embodiments, a first flow of ambient air 20 may be ingested at a first intake 18a and a second flow of ambient air 20 may be ingested at a second intake 18b. A first portion of the first flow and a first portion of the second flow of the ingested ambient air 20 may travel into the communications box 16. A second portion of the first flow and a second portion of the second flow of the ambient air 20 may travel along or into the first and second electronic display subassemblies 14a, 14b, respectively. The first portion and the second portion may travel through one or more of the apertures 27 in the convection aperture plate 26. The ambient air 20 may circulate within some or all of the communications box 16. The ambient air 20 may exit the communications box 16 by way of the vent 28.

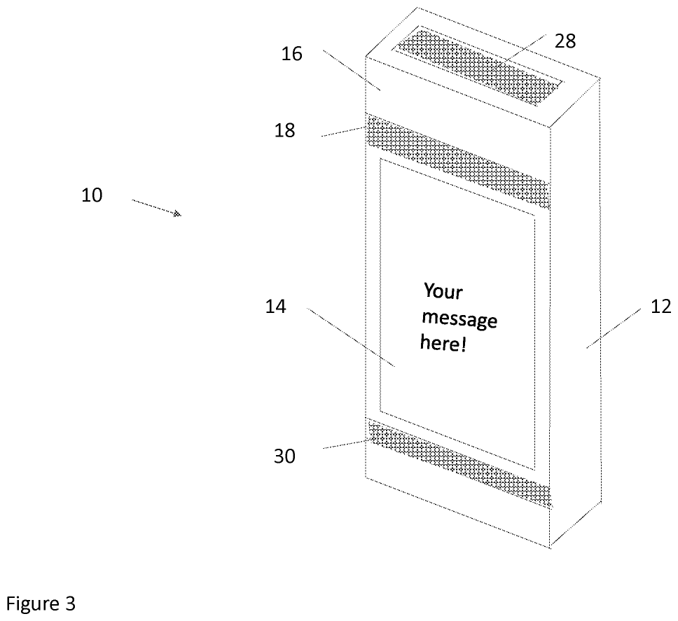

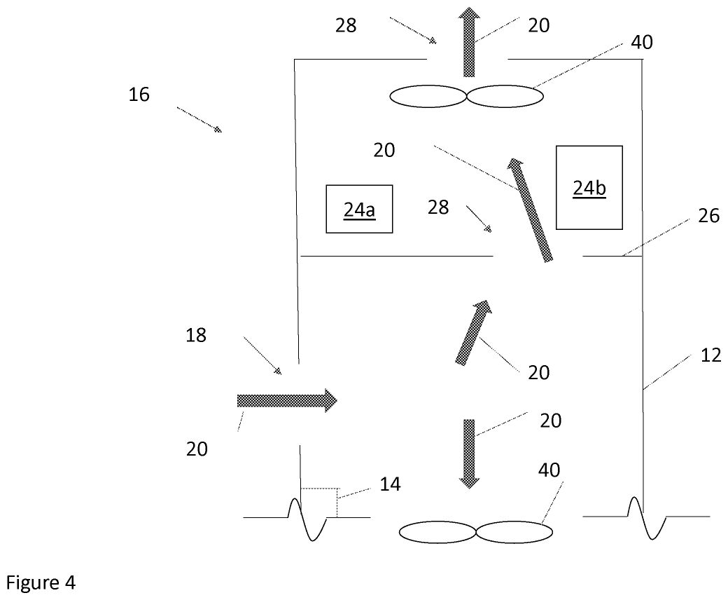

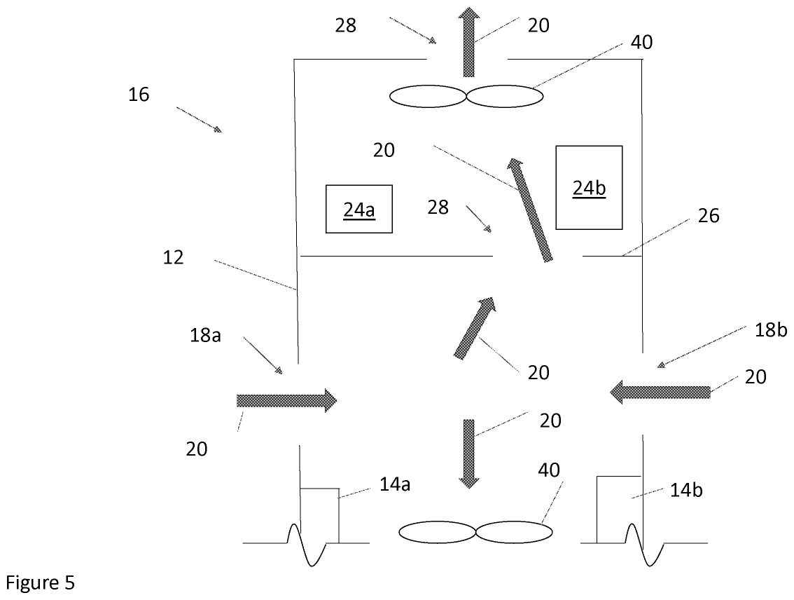

FIG. 3 illustrates another exemplary display assembly 10. FIG. 4 illustrates an exemplary airflow configuration for a display assembly 10 having a single electronic display subassembly 14. FIG. 5 illustrates an exemplary airflow configuration for a display assembly 10 having multiple electronic display subassemblies 14. Any number of electronic display subassemblies 14 with any size or shape housing 12 may be utilized.

One or more fans 40 may be provided within the communications box 16 to force the flow of ambient air 20 through the convection aperture plate 26 and the communications box 16 when activated. While illustrated as being proximate to the vent 28, one or more such fans 40 may alternatively or additionally be located proximate to the intakes 18 or elsewhere within or adjacent to the communications box 16. The fan(s) 40 may be of the same or different type and may comprise, for example, without limitation, axial fans, centrifugal fans, or the like. The fans 40 may comprise axial fans, centrifugal fans, combinations thereof, or the like.

Other fans 40 may be provided at various locations within the assembly 10, such as to force ambient air 20 along or through the electronic display assemblies 14, the housing 12, or other locations within the assembly 10. The display assemblies 10 may utilize one or more open loop airflow pathways, one or more closed loop airflow pathways, combinations thereof, or the like.

In exemplary embodiments, at least one of the electronic components 24 may comprise a sensor, and readings from the sensor may be used to adjust operations of the fan(s) 40. For example, without limitation, the electronic components 24 may comprise a temperature sensor, and fan 40 speed may be increased and/or additional fans 40 may be activated as temperatures rise (e.g., during daytime hours and/or during warmer days) and fan 40 speed may be decreased and/or fans 40 may be deactivated as temperatures fall (e.g., during nighttime hours and/or cooler days).

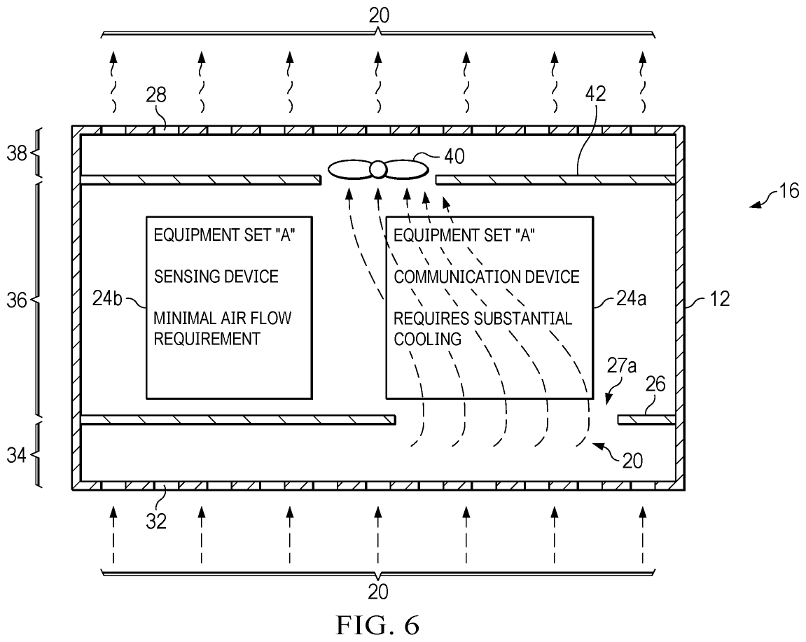

FIG. 6 illustrates another exemplary communications box 16. In the illustrated embodiment, which is provided, for example, but without limitation, ambient air 20 may be ingested into the communications box 16 by way of an intake portion 32. The ingested ambient air 20 may be directed through at least one aperture 27a proximate a first set of electronic equipment 24a. For example, without limitation, the first set of electronic equipment 24a may comprise communication devices which require substantial cooling. The airflow 20 may be directed away from a second set of electronic equipment 24b due to a lack of apertures 27 in the convection aperture plate 26 proximate to the second set of electronic equipment 24b. For example, without limitation, the second set of electronic equipment 24b may comprise sensing devices which require minimal to no airflow.

The communications box 16 may comprise an intake portion 32. The communications box 16 may comprise a vent 28. The intake portion 32 may extend along some or all of a lower surface of the communications box 16, though other locations may be utilized. The intake portion 32 may be configured to receive some or all of the ambient air 20 ingested through the intakes 18. The vent 28 may extend along some or all of an upper surface of the communications box 16, though other locations may be utilized. The vent 28 may be configured to exhaust some or all of the ambient air received within the communications box 16. An air inlet plenum 34 may be formed between the intake portion 32 and the convection aperture plate 26. An equipment cavity 36 may be formed between the convection aperture plate 26 and a mounting surface 42 for the fan(s) 40. The electronic equipment 24 may be secured within the equipment cavity 36. An air outlet plenum 38 may be provided between the mounting surface 42 and the vent 28. In other exemplary embodiments, the intake portion 32 and/or the mounting surface 40 are not required or are of varying size and shape.

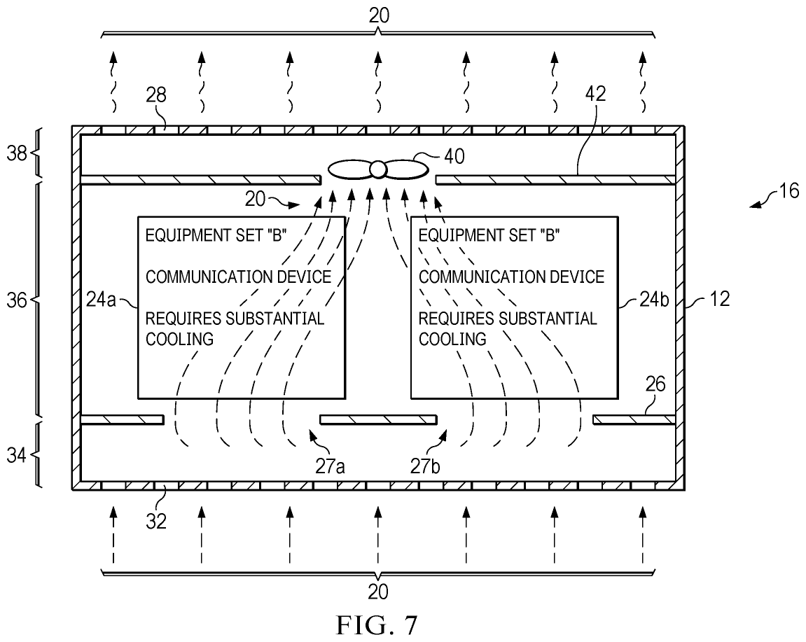

FIG. 7 illustrates the communications box 16 with another exemplary convection aperture plate 26. The convection aperture plate 26 may comprise at least a first aperture 27a proximate one or more first items of equipment 24a and a second aperture 27b proximate to one or more second items of equipment 24b. In this way, a portion of the ambient air 20 entering the communications box 16 may be directed to the first set of equipment 24a and a second portion of the ambient air 20 may be directed to the second set of equipment 24b. For example, without limitation, both the first and second sets of equipment 24a, 24b may require cooling for operation.

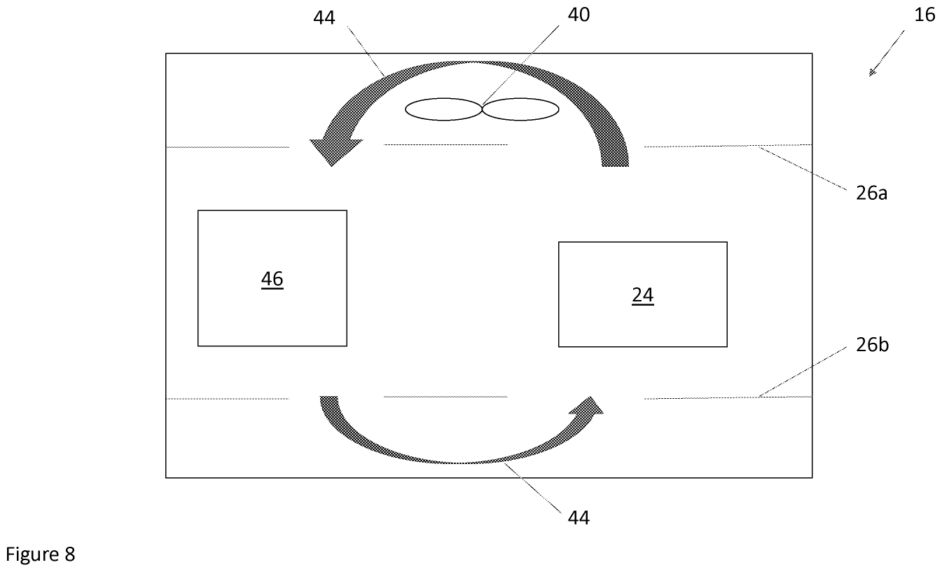

FIG. 8 illustrates another exemplary embodiment of the communications box 16. The communications box 16 may be wholly or partially sealed such that circulating gas 44 flows within the communications box 16. One or more convection aperture plates 26a, 26b may be located with the communications box 16. One or more thermal management devices 46 may be located within, or be in fluid communication with, the communications box 16. The thermal management devices 46 may include, for example, without limitation, heat exchangers, thermoelectric cooling devices, heat sinks, some combination thereof, or the like. One or more fans 40 may be provided to circulate the circulating gas 44 within the communications box 16. Heat may be removed from, or imparted to, the circulating gas 44 by the thermal management devices 46.

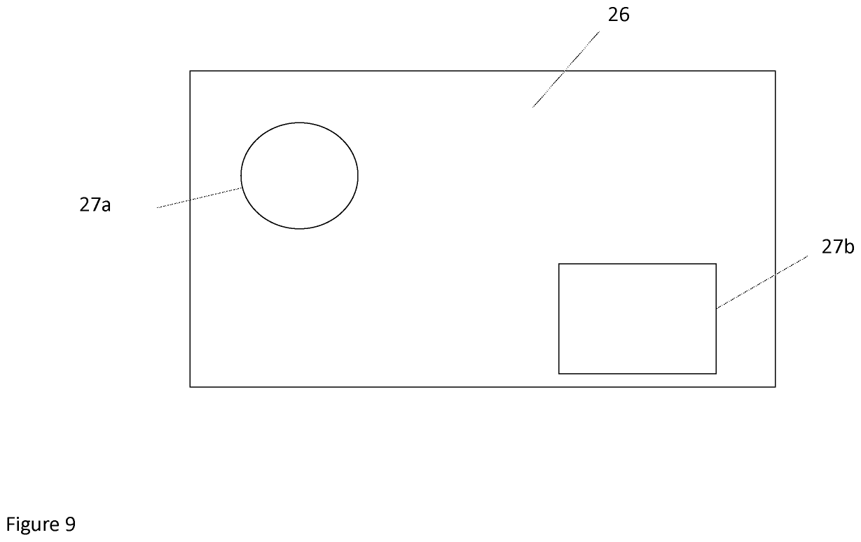

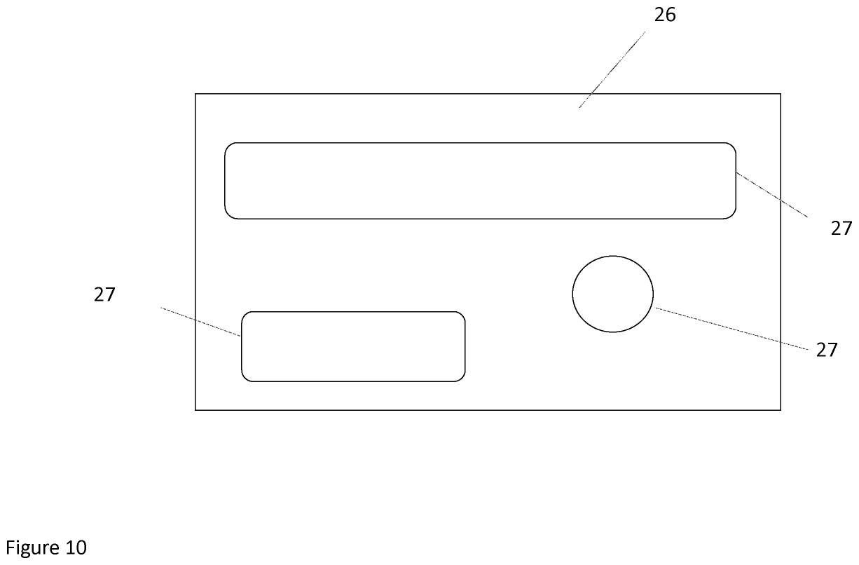

FIG. 9 and FIG. 10 illustrate exemplary convection aperture plates 26. One or more apertures 27 may be provided about the convection aperture plate 26. The apertures 27 may be of the same or different size and shape. Any number of apertures 27 may be provided in any arrangement. The apertures 27 may be placed proximate to certain electronic components 24 of the communications box 16, though such is not required.

Those of skill in the art will appreciate that the convection aperture plate 26 may be utilized, alternatively or additionally, at locations within the assembly 10 other than the communications box 16. For example, without limitation, the convection aperture plate 26 may be utilized between electronic display subassemblies 14, below the electronic display subassemblies 14, combinations thereof, or the like.

Multiple convection aperture plates 26 may be used within the communications box 16 and/or the display assembly 10. Such convection aperture plates 26 may be of the same or different type. For example, without limitation, a convection aperture plate 26 may be used in place of one or more of the mounting surface 42, the vent 28, and/or the intake portion 32. As another example, without limitation, a first convection aperture plate 26 may be used in the communications box 16 and a second convection aperture plate 26 may be utilized between the electronic display subassemblies 14.

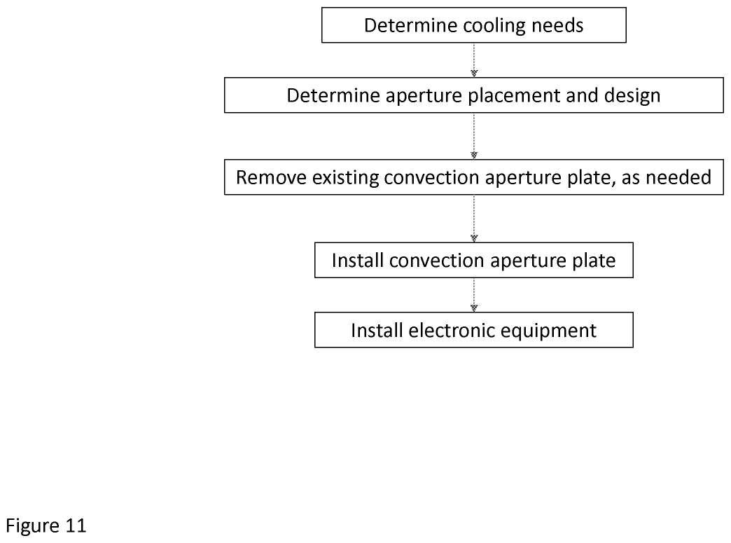

FIG. 11 illustrates steps for fitting a communications box 16 with a convection aperture plate 26. The communication box 16 may be retrofitted with one or more convection aperture plates 26. Such retrofitting may be performed to improve airflow for existing electronic components 24 and/or to optimize airflow for new electronic components 24 previously installed, concurrently installed, or to be installed in the future. Alternatively, or additionally, existing convection aperture plates 26 may be removed from communications boxes 16 and replaced with convection aperture plates 26, which may be configured to optimize airflow for new electronic equipment 24 previously installed at, concurrently installed at, or to be installed at, the communications box 16. Design and placement of apertures 27 in the convection aperture plates 26 may be accomplished using various manual or computerized flow analysis techniques.

The convection aperture plates 26 may be integrally formed with, welded, soldered, brazed, bonded, adhered, some combination thereof, or the like to the communications box 16. The convection aperture plates 26 may be cut out and replaced as needed. In other exemplary embodiments, the convection aperture plates 26 may be configured for faster removal, such as by way of fasteners, snap fittings, pressure fittings, friction fit, combinations thereof, or the like.

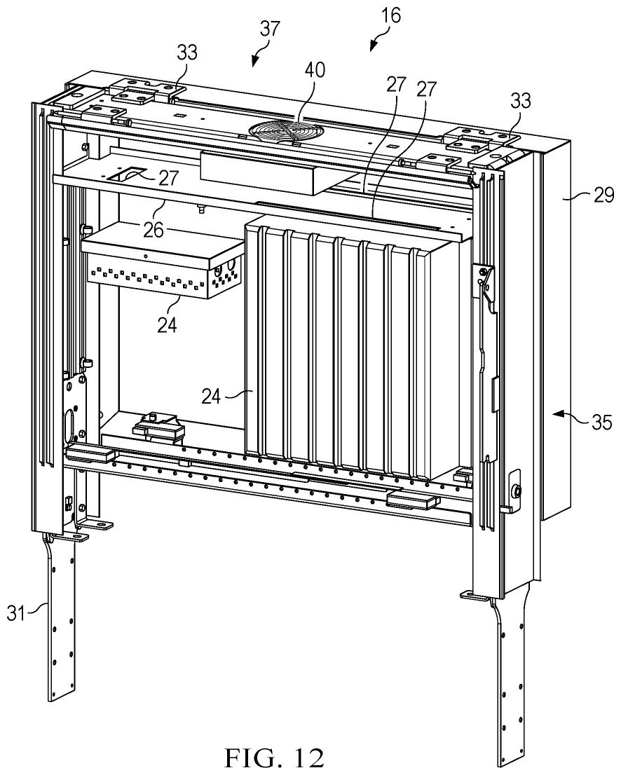

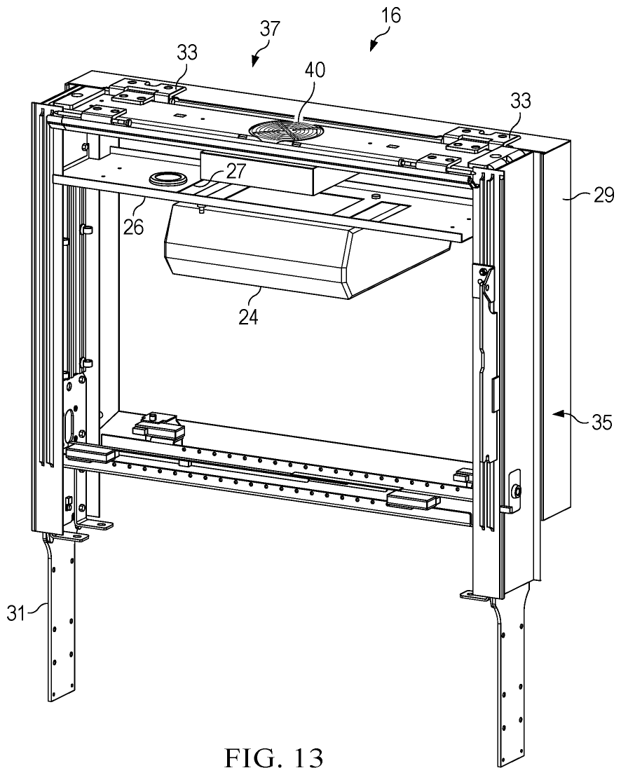

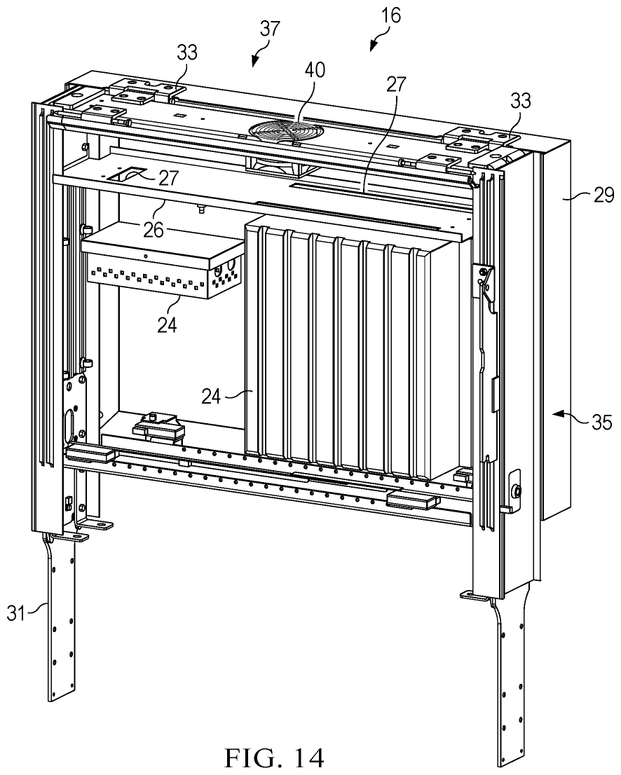

FIG. 12 through FIG. 14 illustrate other exemplary communications boxes 16. Each communications box 16 may, in exemplary embodiments, comprise one or more access panels 29. Each of the access panels 29 may be connected to a frame 31 in a moveable manner, such as, but not limited to, by way of one or more hinging devices 33. A gap 35 may be provided along some or all of a perimeter of the access panel 29 between the access panel 29 and the frame 31. For example, without limitation, the gap 35 may be located between a bottom portion of the access panel 29 and the adjacent portion of the frame 31. The gap 35 may serve as a vent 28 for exhausting ambient air. Where more than one access panel 29 is provided, more than one gap 35 may be provided. In exemplary embodiments, a first and second access panel 29 is provided on opposing sides of said frame 31.

The frame 31 may be connected to housing 12. Alternatively, or additionally, the frame 31 may form at least a portion of the housing 12. The frame 31 and/or the housing 12 may comprise multiple components. One or more openings 37 may be provided at the communications box 16 for ingesting and/or exhausting ambient air to or from the communications box 16. The openings 37 may be positioned adjacent to each of the fans 40.

The fans 40 may be configured to pull air through the gap 35 and through the apertures 27 in the convection aperture plate 26 before being exhausted from the communications box 16, such as by way of the openings 37. In other exemplary embodiments, the fans 40 may be configured to ingest air, such as by way of the openings 37, which is pushed through the apertures 27 in the convection aperture plate 26 before being exhausted from the communications box 16 by way of the gap 35. In such embodiments, the airflow for the communications box 16 may be fluidly separated from the airflow for the electronic display subassemblies 14.

In exemplary embodiments, the fans 40 and/or the electronic components 24 may be mounted to the convection aperture plate 26. In such embodiments, a separate mounting surface 42 may not be required. Alternatively, or additionally, the fans 40 may be mounted to a portion of the frame 31 and/or the access panels 29. The electronic components 24 may, alternatively or additionally, be mounted to the access panels 29.

One or more convection aperture plates 26 may be provided at various locations within the communications box 16 and/or elsewhere within the display assembly 10. For example, without limitation, the convection aperture plate 26 may be located upstream and/or downstream of electronic equipment 24 within the communications box 16. The location of the convection aperture plate 26 may be changed when new such electronic equipment 24 is installed or relocated within the communications box 16 or elsewhere within the display assembly 10.

Apertures 27 may be provided at the convection aperture plate 26 adjacent to certain electronic components 24, but not others. Solid material and/or different size, shape, and/or type of apertures 27 may be provided at the convection aperture plate 26 adjacent to other certain electronic components 24. The convection aperture plate 26 may be placed upstream, downstream, or otherwise of the electronic components 24 relative to the openings 37.

Any embodiment of the present invention may include any of the features of the other embodiments of the present invention. The exemplary embodiments herein disclosed are not intended to be exhaustive or to unnecessarily limit the scope of the invention. The exemplary embodiments were chosen and described in order to explain the principles of the present invention so that others skilled in the art may practice the invention. Having shown and described exemplary embodiments of the present invention, those skilled in the art will realize that many variations and modifications may be made to the described invention. Many of those variations and modifications will provide the same result and fall within the spirit of the claimed invention. It is the intention, therefore, to limit the invention only as indicated by the scope of the claims.

Certain operations described herein may be performed by one or more electronic devices. Each electronic device may comprise one or more processors, electronic storage devices, executable software instructions, and the like configured to perform the operations described herein. The electronic devices may be general purpose computers or specialized computing devices. The electronic devices may comprise personal computers, smartphones, tablets, databases, servers, or the like. The electronic connections and transmissions described herein may be accomplished by wired or wireless means. The computerized hardware, software, components, systems, steps, methods, and/or processes described herein may serve to improve the speed of the computerized hardware, software, systems, steps, methods, and/or processes described herein.

What is claimed is:

1. A communications apparatus, comprising:
a vertically extending structural housing having at least two zones;
an electronic display secured within a first zone of the structural housing, said electronic display adapted to communicate visual information;
a communications sub-structure secured within a second zone of said housing, wherein said sub-structure contains communications electronics components;
a convection partition comprising at least one aperture, said convection partition separating an interior of said communications sub-structure, wherein said at least one aperture is positioned adjacent to a first electronic component of the sub-structure to facilitate air flow cooling of said first electronic component; and
at least one fan secured within said housing to facilitate ambient airflow from an intake in said housing, through said at least one aperture, and out an exhaust in said housing.

2. The communications apparatus of claim 1 further comprising:
an intake;
an exhaust; and
one or more fans configured to, when activated, cause a flow of ambient air to be accepted at said intake, forced through each of said one or more apertures in said convection partition, and exhausted through said exhaust.

3. A communications box for a display assembly providing directed airflow, said communications box comprising a partition comprising at least one aperture and separating an interior of said communications box into an upper area and a lower area, wherein said at least one aperture is positioned adjacent to a first electronic component of the communications box which requires active cooling, and a solid surface of said partition is positioned adjacent to a second electronic component of the communications box which does not require active cooling.

4. The communications apparatus of claim 3 further comprising:
an intake;
an exhaust; and
one or more fans configured to, when activated, cause a flow of ambient air to be accepted at said intake, directed through each of said one or more apertures in said partition, and exhausted through said exhaust.

5. A communications apparatus, comprising:
a structural housing having at least two zones;
an electronic display secured within, and/or forming part of, a first zone of the structural housing, said electronic display adapted to communicate visual information; and
the communications box of claim 3 secured within, and/or forming part of, a second zone of the structural housing.

6. The communications apparatus of claim 5 wherein:
the second zone is located above the first zone.

7. The communications apparatus of claim 6 wherein:
the second zone is spaced apart from the first zone.

8. The communications apparatus of claim 5 wherein:
the partition comprises a panel spanning the interior of said communications box to separate the upper area and the lower area.

9. The communications apparatus of claim 5 wherein:
the electronic display comprises a liquid crystal display.

10. An apparatus comprising:
a communications box defining an interior space;
a plurality of electronic components disposed within the interior space of the communications box, the plurality of electronic components comprising a first electronic component having a first airflow requirement;
a convection partition disposed within the interior space of the communications box, wherein the convection partition divides the interior space and comprises one or more apertures, wherein the convection partition forms a barrier within the communications box such that air within the communications box is directed to travel through the one or more apertures, and wherein the convection partition comprises at least one aperture of the one or more apertures positioned adjacent to a planned or actual location of the first electronic component; and
one or more fans positioned to direct, when activated, a flow of air within the communications box and through each of the one or more apertures in the convection partition.

11. The apparatus of claim 10, wherein:
the plurality of electronic components comprises a second electronic component having a second airflow requirement; and
the convection partition comprises a solid material positioned adjacent to a planned or actual location of the second electronic component.

12. The apparatus of claim 11, wherein:
the first electronic component comprises communications equipment and the second electronic component comprises a sensor.

13. The apparatus of claim 10, wherein:
at least one electronic component of the plurality of electronic components comprises a temperature sensor, and wherein the one or more fans are configured to adjust operations based on one or more readings from the temperature sensor, including by increasing a speed of at least one fan of the one or more fans, or activating an additional fan, as a temperature indicated by the one or more readings rises.

14. The apparatus of claim 10, wherein:
the convection partition is substantially planar and defines a footprint matching a footprint of the interior space of the communications box, such that the convection partition spans the interior space and divides the interior space into an upper portion and a lower portion.

15. The apparatus of claim 10, further comprising:
an intake at the communications box;
a vent at the communications box; and
a mounting surface for the one or more fans, wherein an air inlet plenum is defined between the intake and the convection partition, an equipment cavity within which the plurality of electronic components are secured is defined between the convection partition and the mounting surface, and an air outlet plenum is defined between the mounting surface and the vent.

16. The apparatus of claim 10, further comprising:
an electronic display subassembly;
a frame interconnecting the communications box and the electronic display subassembly such that the communications box is located above and spaced apart from the electronic display subassembly; and
a common intake located between the communications box and the electronic display subassembly, wherein the common intake is configured to ingest a common flow of ambient air comprising the flow of air directed within the communications box and a separate flow of ambient air for the electronic display subassembly.

17. The apparatus of claim 10, further comprising:
a thermal management device positioned within the communications box, said thermal management device selected from the group consisting of: a heat exchanger, a thermoelectric cooling device, and a heat sink.

18. The apparatus of claim 10, further comprising:
a frame and one or more access panels connected to the frame in a manner permitting hinging movement of the one or more access panels to permit access to the interior space of the communications box, wherein a gap between the one or more access panels and the frame defines a vent through which the flow of air is exhausted from the communications box.

19. The apparatus of claim 10, wherein:
at least one fan of the one or more fans is mounted to the convection partition, at least one electronic component of the plurality of electronic components is mounted to the convection partition, or both.
